(19) United States
(12) Patent Application Publication
(10) Pub. No.: US 2025/0098544 A1
(43) Pub. Date: Mar. 20, 2025

(54) MANUFACTURING APPARATUS AND MEMORY DEVICE

(71) Applicant: Kioxia Corporation, Tokyo (JP)

(72) Inventors: Takuya SHIMANO, Seoul (KR); Kenichi YOSHINO, Seongnam-si Gyeonggi-do (KR); Naoki AKIYAMA, Seoul (KR)

(73) Assignee: Kioxia Corporation, Tokyo (JP)

(21) Appl. No.: 18/829,993

(22) Filed: Sep. 10, 2024

(30) Foreign Application Priority Data
Sep. 20, 2023 (JP) 2023-152253

(51) Int. Cl. H10N 50/01; H10B 61/00; H10N 50/10; H10N 50/80

(52) U.S. Cl. CPC H10N 50/01; H10B 61/10; H10N 50/10; H10N 50/80

(57) ABSTRACT

According to one embodiment, a manufacturing apparatus includes: a wafer holding unit configured to hold a wafer; an ion source configured to output an ion beam; a shutter holding unit configured to hold a shutter and place the shutter between the wafer holding unit and the ion source in a case of preventing irradiation of the wafer with the ion beam; and a target holding unit configured to hold a target including a through hole, and place the target between the wafer holding unit and the ion source in a case of forming, on the wafer, a first layer including a member of the target.

### CROSS-REFERENCE TO RELATED APPLICATIONS

This application is based upon and claims the benefit of priority from prior Japanese Patent Application No. 2023-152253, filed Sep. 20, 2023, the entire contents of which are incorporated herein by reference.

### FIELD

Embodiments described herein relate generally to a manufacturing apparatus and a memory device.

### BACKGROUND

A magnetic memory using a magnetoresistive effect element as a memory element is known.

### BRIEF DESCRIPTION OF THE DRAWINGS

FIG. 1 is a block diagram for explaining a configuration of a memory device according to a first embodiment.

FIG. 2 is a circuit diagram for explaining a configuration of a memory cell array of the memory device according to the first embodiment.

FIG. 3 is a plan view for explaining a configuration of the memory cell array of the memory device according to the first embodiment.

FIG. 4 is a cross-sectional view taken along the line IV-IV of FIG. 3, showing an example of a cross-sectional structure of the memory cell array of the memory device according to the first embodiment.

FIG. 5 is a cross-sectional view for explaining a configuration of a memory element of the memory device according to the first embodiment.

FIG. 6 is a block diagram showing a system including a manufacturing apparatus according to the first embodiment.

FIG. 7 is a schematic diagram for explaining the configuration of the manufacturing apparatus according to the first embodiment.

FIG. 8 is a plan view showing a configuration of a member used in the manufacturing apparatus according to the first embodiment.

FIG. 9 is a cross-sectional process diagram showing a process in a memory device manufacturing method according to the first embodiment.

FIG. 10 is a schematic diagram showing a state of the manufacturing apparatus according to the first embodiment in a memory device manufacturing process.

FIG. 11 is a schematic diagram showing a state of the manufacturing apparatus according to the first embodiment in the memory device manufacturing process.

FIG. 12 is a cross-sectional process diagram showing a process in the memory device manufacturing method according to the first embodiment.

FIG. 13 is a schematic diagram showing a state of the manufacturing apparatus according to the first embodiment in the memory device manufacturing process.

FIG. 14 is a cross-sectional process diagram showing a process in the memory device manufacturing method according to the first embodiment.

FIG. 15 is a schematic diagram for explaining the configuration of a manufacturing apparatus according to a second embodiment.

FIG. 16 is a schematic diagram showing a state of the manufacturing apparatus according to the second embodiment in a memory device manufacturing process.

FIG. 17 is a schematic diagram showing a state of the manufacturing apparatus according to the second embodiment in the memory device manufacturing process.

FIG. 18 is a diagram showing a modification of the memory device according to one or more of the embodiments.

FIG. 19 is a diagram showing a modification of the manufacturing apparatus according to one or more of the embodiments.

FIG. 20 is a diagram showing a modification of the memory device manufacturing method according to one or more of the embodiments.

### DETAILED DESCRIPTION

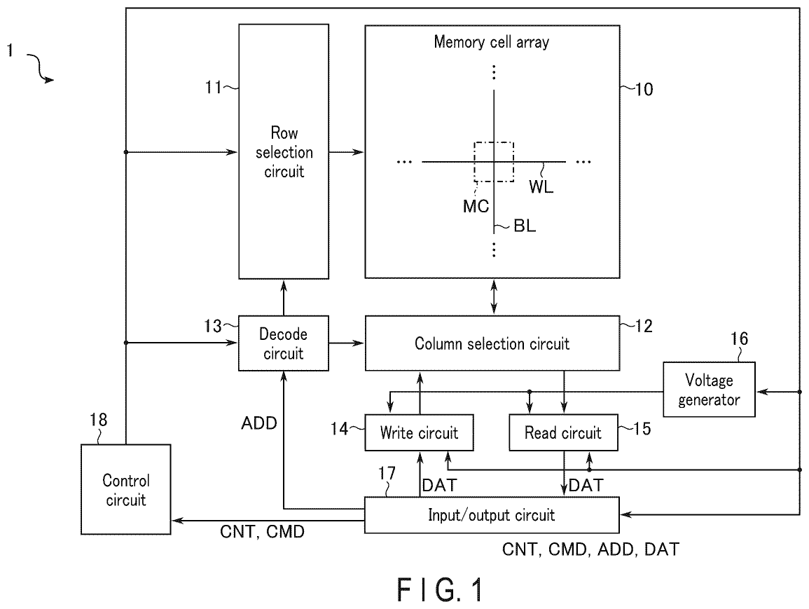

A manufacturing apparatus according to one embodiment, a memory device according to one embodiment, and a memory device manufacturing method according to one embodiment will be described with reference to FIGS. 1 to 20. In the following description, elements having the same function and configuration are denoted by the same reference numerals. Further, in each of the following embodiments, in a case where the components (for example, circuits, interconnects, various voltages and signals, and the like) with distinguishing reference numerals or letters in the end are not necessarily distinguished from each other, a description (reference numeral) in which the numerals or letters in the end are omitted is used. In addition, in each of the following embodiments, a case where “a/b layer” indicates a layered structure of a layer containing an element a and a layer containing an element b. In this case, the layer containing the element a is stacked on the layer containing the element b.

### EMBODIMENTS

### 1. First Embodiment

A memory device according to a first embodiment, a manufacturing apparatus according to the first embodiment, and a memory device manufacturing method according to the first embodiment will be described with reference to FIGS. 1 to 14.

The memory device according to the embodiment includes, for example, a magnetic memory using an element having a magnetoresistive effect by a magnetic tunnel junction as a resistance change element. Hereinafter, an element (magnetoresistive effect element) having a magnetoresistive effect by a magnetic tunnel junction is also referred to as an MTJ element.

### 1.1 Configuration

A configuration of the memory device according to the first embodiment will be described with reference to FIGS. 1 to 5.

### 1.1.1 Configuration of Memory Device

FIG. 1 is a block diagram showing a configuration of a magnetic memory as a memory device 1 according to the present embodiment. As shown in FIG. 1, the magnetic memory 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC each associated with a set of a row and a column. The memory cells MC in a same row are connected to a same word line WL. The memory cells MC in a same column are connected to a same bit line BL.

The row selection circuit 11 is connected to the memory cell array 10 via a word line WL. A decoding result (a row address) of an address ADD from the decode circuit 13 is supplied to the row selection circuit 11. The row selection circuit 11 sets, in a selected sate, the word line WL corresponding to the row based on the decoding result of the address ADD. Hereinafter, the word line WL set to the selected state is referred to as a selected word line WL. The word lines WL other than the selected word line WL are referred to as unselected word lines WL.

The column selection circuit 12 is connected to the memory cell array 10 via a bit line BL. The decoding result (a column address) of the address ADD from the decode circuit 13 is supplied to the column selection circuit 12. The column selection circuit 12 sets, in a selected state, the bit line BL corresponding to the column based on the decoding result of the address ADD. Hereinafter, the bit line BL set to the selected state is referred to as a selected bit line BL. The bit lines BL other than the selected bit line BL are referred to as unselected bit lines BL.

The decode circuit 13 decodes the address ADD from the input/output circuit 17. The decode circuit 13 supplies a decoding result of the address ADD to the row selection circuit 11 and the column selection circuit 12. The address ADD includes a column address and a row address to be selected.

The write circuit 14 writes data to the memory cell MC. The write circuit 14 includes, for example, a write driver (not illustrated).

The read circuit 15 reads data from the memory cell MC. The read circuit 15 includes, for example, a sense amplifier (not illustrated).

The voltage generator 16 generates voltage for various operations of the memory cell array 10 using the power supply voltage. The power supply voltage is provided from a device (not illustrated) outside the magnetic memory 1. For example, the voltage generator 16 generates various voltages used for the write operation and outputs the voltages to the write circuit 14. For example, the voltage generator 16 generates various voltages used for the read operation and outputs the voltages to the read circuit 15.

The input/output circuit 17 manages communication with a device outside the magnetic memory 1. The input/output circuit 17 transfers the address ADD from the outside of the magnetic memory 1 to the decode circuit 13. The input/output circuit 17 transfers a command CMD from the outside of the magnetic memory 1 to the control circuit 18. The input/output circuit 17 transmits and receives various control signals CNT between the outside of the magnetic memory 1 and the control circuit 18. The input/output circuit 17 transfers data DAT from the outside of the magnetic memory 1 to the write circuit 14. The input/output circuit 17 outputs the data DAT transferred from the read circuit 15 to the outside of the magnetic memory 1.

The control circuit 18 controls operations of the row selection circuit 11, the column selection circuit 12, the decode circuit 13, the write circuit 14, the read circuit 15, the voltage generator 16, and the input/output circuit 17 in the magnetic memory 1 based on the control signal CNT and the command CMD.

### 1.1.2 Configuration of Memory Cell Array

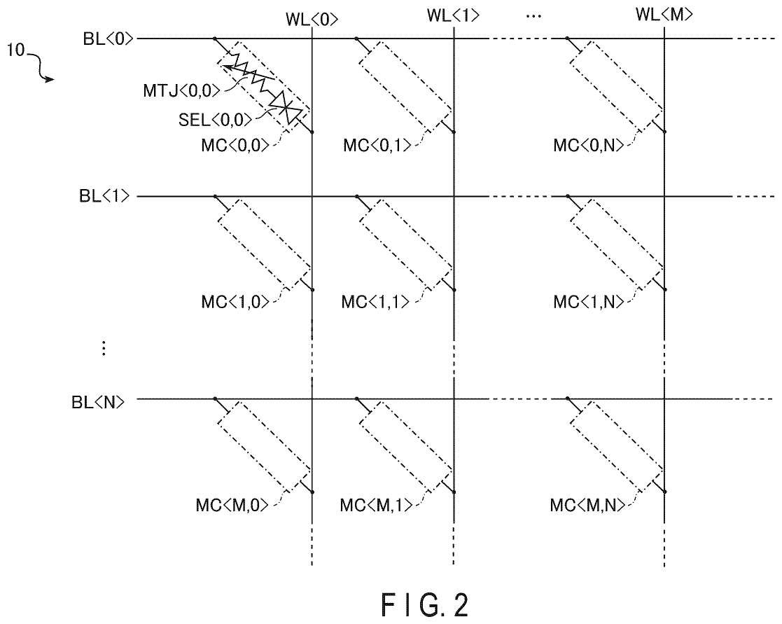

A configuration of the memory cell array of the magnetic memory 1 according to the present embodiment will be described with reference to FIG. 2. FIG. 2 is a circuit diagram showing a configuration of the memory cell array of the magnetic memory according to the embodiment. In FIG. 2, the word lines WL are distinguished by the subscripts including indexes “< >”.

According to the present embodiment, the magnetic memory 1 is, for example, a magnetoresistive random access memory (MRAM).

As shown in FIG. 2, the memory cells MC are arranged in a matrix manner in the memory cell array 10. Each memory cell MC is associated with a set of one of the bit lines BL (BL<0>, BL<1>, . . . , BL<N>) and one of the word lines WL (WL<0>, WL<1>, . . . , WL<M>). Here, M and N are natural numbers. The memory cell MC<i, j> (0≤i≤M, 0≤j≤N) is connected between the word line WL<i> and the bit line BL<j>.

The memory cell MC<i, j> includes a switching element SEL<i, j> and a magnetoresistive effect element MTJ<i, j> connected in series. For example, one end of the switching element SEL is connected to the word line WL. The other end of the switching element SEL is connected to one end of the magnetoresistive effect element MTJ. The other end of the magnetoresistive effect element MTJ is connected to the bit line BL.

The switching element SEL is a two-terminal switching element. The two-terminal switching element is different from a three-terminal switching element such as a transistor in that a third terminal is not included. In a case where the voltage applied between the two terminals is less than a threshold voltage Vth (the voltage applied between the two terminals<the threshold voltage Vth), the switching element SEL is in a high resistance state. The high resistance state is, for example, an “off” state in which the switching element SEL is in an electrically non-conductive state. In a case where the voltage applied between the two terminals is equal to or higher than the threshold voltage Vth (the voltage applied between the two terminals≥the threshold voltage Vth), the switching element SEL changes to a low resistance state. The low resistance state is, for example, an “on” state in which the switching element SEL is in an electrically conductive state.

For example, in a case where the voltage applied to the corresponding memory cell MC is less than the threshold voltage Vth (the voltage applied to the corresponding memory cell MC<the threshold voltage Vth), the switching element SEL blocks the current as an insulator having a large resistance value. In other words, the switching element SEL is in the off state.

In a case where the voltage applied to the corresponding memory cell MC is equal to or higher than the threshold voltage Vth (the voltage applied to the corresponding memory cell MC≥the threshold voltage Vth), the switching element SEL conducts the current as a conductor with low resistance. In other words, the switching element SEL is in the on state.

The switching element SEL switches whether to conduct or block the current according to the magnitude of the voltage applied to the corresponding memory cell MC regardless of the polarity of the voltage applied between the two terminals (regardless of the direction of the current flow).

The magnetoresistive effect element MTJ can switch its resistance state to a low resistance state or a high resistance state by the current controlled by the switching element SEL. The magnetoresistive effect element MTJ functions as a memory element. According to the change in the resistance state of the magnetoresistive effect element MTJ, data may be written into the magnetoresistive effect element MTJ. The magnetoresistive effect element MTJ holds the written data in a nonvolatile manner. The data may be read from the magnetoresistive effect element MTJ.

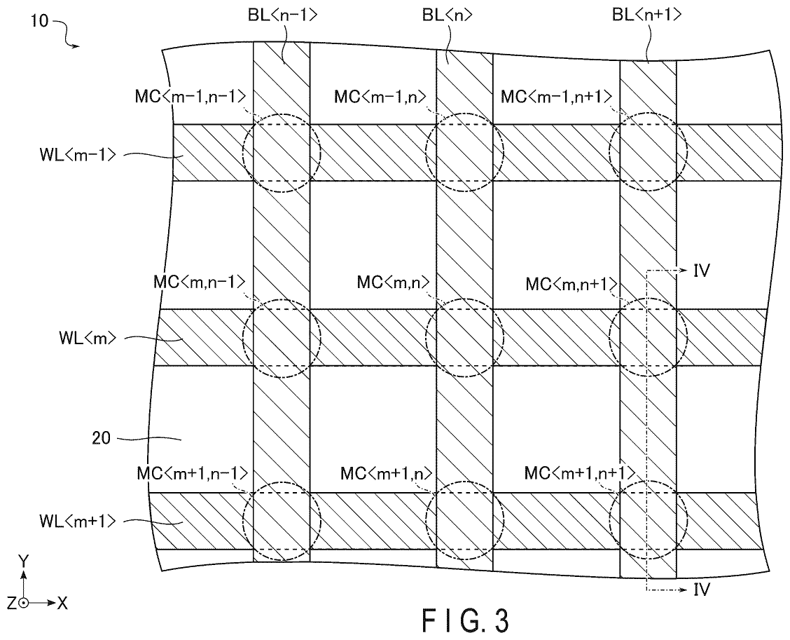

The shape of the memory cells MC in the memory cell array 10 and the arrangement of the memory cells MC with respect to the bit lines BL and the word lines WL will be described with reference to FIG. 3. FIG. 3 illustrates an example of a plan view for explaining an example of a configuration of the memory cell array 10 of the magnetic memory 1 according to the present embodiment. FIG. 3 illustrates a plurality of memory cells MC provided between three word lines WL<m−1>, WL<m>, and WL<m+1> and three bit lines BL<n−1>, BL<n>, and BL<n+1> of the memory cell array 10 (1≤m≤M-1, 1≤ n≤N-1). For convenience of description, the interlayer insulating film is omitted in FIG. 3.

As shown in FIG. 3, the memory cell array 10 is provided above a substrate 20. In the following description, a plane parallel to a surface of the substrate 20 is referred to as an XY plane. A direction perpendicular to the XY plane is referred to as a Z direction. The two directions parallel to the XY plane are referred to as an X direction and a Y direction. The X direction and the Y direction are orthogonal to each other.

The memory cells MC are provided between the word lines WL and the bit lines BL. In the example of FIG. 3, the word lines WL are provided below the memory cells MC, and the bit lines BL are provided above the memory cells MC. However, the vertical relationship between the word lines WL and the bit lines BL may be reversed.

Each of the memory cells MC has, for example, a circular planar shape along the XY cross section.

The word lines WL are arranged along the Y direction. Each of the word lines WL extends along the X direction. The bit lines BL are arranged along the X direction. Each of the bit lines BL extends along the Y direction. The distance (interval) between the two of the word lines WL can be set to be substantially equal to the distance between the two of the bit lines BL, for example. One memory cell MC is provided at a portion where one bit line BL and one word line WL intersect.

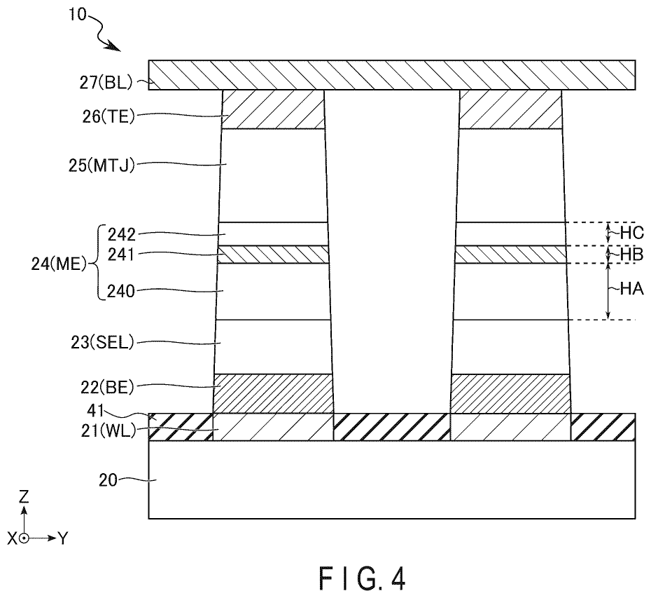

With reference to FIG. 4, a cross-sectional structure of the memory cell array 10 will be described. FIG. 4 is a cross-sectional view showing an example of a cross-sectional structure of the memory cell array of the magnetic memory according to the embodiment. The cross section in FIG. 4 is taken along the line IV-IV in FIG. 3.

The memory cell array 10 is provided above the semiconductor substrate 20.

The memory cell array 10 includes a plurality of conductors 21, a plurality of electrodes 22, a plurality of elements (variable resistance layers) 23, a plurality of electrodes 24, a plurality of elements 25, a plurality of electrodes 26, and a plurality of conductors 27.

For example, the conductors 21 are provided on an upper surface of the substrate 20. The conductors 21 are arranged along the Y direction. Each of the conductors 21 extends along the X direction in a region (not illustrated). Each of the conductors 21 functions as a word line WL. An insulator 41 is provided in a portion between two adjacent conductors 21. With this configuration, each of the conductors 21 is insulated from each other.

In FIG. 4, the case where the conductors 21 are provided on the substrate 20 has been described, but the present embodiment is not limited the case. For example, the conductors 21 may be provided away from the substrate 20 without being in contact with the substrate 20. For example, in a case where the substrate 20 is a semiconductor substrate, an insulating layer (interlayer insulating film) is provided between the substrate 20 and the conductors 21. In this case, an element such as a field effect transistor is provided on the upper surface of the semiconductor substrate 20 so as to be covered with the insulating layer. The field effect transistor is an element constituting a CMOS circuit such as a row selection circuit.

The electrodes 22 are provided on an upper surface of the conductors 21 respectively. The electrodes 22 provided on the upper surface of the same conductors 21 are arranged in the X direction in an unillustrated region. In FIG. 4, the two electrodes 22 provided on the two conductors 21 out of the electrodes 22 are illustrated. Each of the electrodes 22 is used as a lower electrode BE of the memory cell MC.

One corresponding element 23 of the elements 23 is provided on an upper surface of each of the electrodes 22. Each of the elements 23 is used as a switching element SEL. The element 23 includes at least one layer (a variable resistance layer).

One corresponding electrode 24 of the electrodes 24 is provided on an upper surface of each of the elements 23. Each of the electrodes 24 functions as an intermediate electrode ME of the memory cell MC. Details of the configuration of the electrode 24 will be described later.

One corresponding element 25 of the elements 25 is provided on an upper surface of each of the electrodes 24. Each of the elements 25 functions as a memory element. The element 25 is, for example, a magnetoresistive effect element MTJ. Details of the configuration of the element 25 will be described later.

One corresponding electrode 26 of the electrodes 26 is provided on an upper surface of each of the elements 25. Each of the electrodes 26 is used as an upper electrode TE of the memory cell MC.

One conductor 27 extending in the Y direction is provided so as to be in contact with an upper surface of each of the electrodes 26 arranged in the Y direction. The conductors 27 are arranged in the X direction in an unillustrated region. Each of the conductors 27 extends along the Y direction. Each of the conductors 27 functions as a bit line BL.

### 1.1.3 Switching Element

The configuration of the switching element SEL (23) of the magnetic memory 1 according to the present embodiment will be subsequently described with reference to FIG. 4.

The element 23 used as the switching element SEL includes a variable resistance layer (also referred to as a selector layer). The resistance state of the element 23 of the variable resistance layer becomes a high resistance state (non-conductive state) or a low resistance state (conductive state) according to the voltage applied to the switching element SEL (memory cell MC).

The element (variable resistance layer) 23 includes (contains) at least one element selected from a group including boron (B), aluminum (Al), gallium (Ga), indium (In), carbon (C), silicon (Si), germanium (Ge), tin (Sn), arsenic (As), phosphorus (P), and antimony (Sb).

The element 23 may be, for example, an insulator including a dopant (impurity). The dopant added to the insulator used for the element 23 is an impurity that contributes to electrical conduction in the insulator. An example of the insulator used for the element 23 is silicon oxide. In a case where the material of the element 23 is silicon oxide, for example, phosphorus or arsenic is used as the dopant to be added to the silicon oxide. However, the type of the dopant to be added to the silicon oxide of the element 23 is not limited to the above-described example.

The element 23 may be made of a material having a snapback characteristic.

### 1.1.4 Intermediate Electrode

The configuration of the intermediate electrode ME of the magnetic memory 1 according to the present embodiment will be subsequently described with reference to FIG. 4.

Each of the electrodes 24 includes three conductors (conductive layers) 240, 241, and 242.

The conductor 240 is provided on the upper surface of each of the elements 23. The conductor 240 is, for example, a layer including at least one member selected from carbon (C) and carbon nitride (CN). The conductor 240 preferably has an amorphous structure. The height (thickness) HA from a lower surface to an upper surface of the conductor 240 in the Z direction is, for example, 2 nanometers (nm) or more and 20 nanometers (nm) or less. In a case where the height HA is within the range, the conductor 240 is prevented from peeling off the upper surface of the element 23.

According to the present embodiment, a portion including one or more elements may include unintended impurities different from the elements. The unintended impurities include, for example, an element included in a gas used in a manufacturing process of the magnetic memory 1 and an element mixed into the portion from a member around the portion.

The conductor 241 is provided on an upper surface of the conductor 240. The conductor 241 is, for example, a layer including a high melting point metal element (high melting point metal-containing member). The conductor 241 includes, for example, at least one member selected from a simple substance of a high melting point metal element and a compound of a high melting point metal element. According to the present embodiment, the high melting point metal is, for example, a material having a melting point higher than that of iron (Fe) and cobalt (Co).

Examples of the high melting point metal element simple substance and the high melting point metal element compound used for the conductor 241 include titanium (Ti), tantalum (Ta), tungsten (W), titanium nitride (TiN), tantalum nitride (TaN), and tungsten nitride (WN). The conductor 241 has, for example, a crystal structure. The height (thickness) HB from a lower surface to an upper surface of the conductor 241 in the Z direction is preferably, for example, 0.1 nanometers (nm) or more and 3 nanometers (nm) or less.

The conductor 241 is formed by injecting or depositing a member including a high melting point metal element by a manufacturing apparatus described later.

The conductor 242 is provided on an upper surface of the conductor 241. Similarly to the conductor 240, the conductor 242 is a layer including at least one member selected from, for example, carbon (C) and carbon nitride (CN). The conductor 242 preferably has an amorphous structure. A height (thickness) HC from a lower surface to an upper surface of the conductor 242 in the Z direction is preferably, for example, 0.1 nanometers (nm) or more and 3 nanometers (nm) or less. With respect to the surface roughness (roughness, flatness) of the upper surface of the conductor 242, for example, a parameter Ra indicating the surface roughness is 0.6 nm or less.

### 1.1.5 Magnetoresistive Effect Element

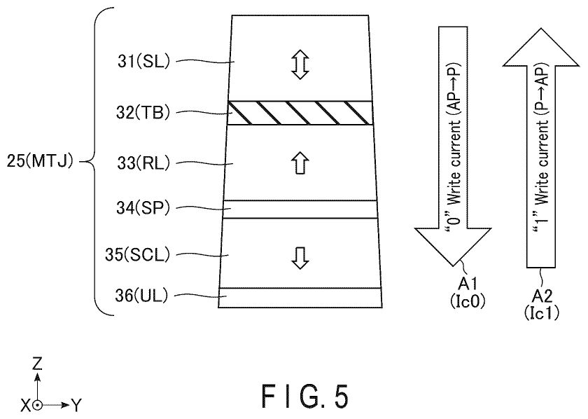

A configuration of the magnetoresistive effect element MTJ of the magnetic memory 1 according to the present embodiment will be described with reference to FIG. 5. FIG. 5 is a cross-sectional view showing a configuration of a magnetoresistive effect element MTJ of the magnetic memory 1 according to the present embodiment.

The element 25 used as the magnetoresistive effect element MTJ includes a ferromagnet 31, a nonmagnet 32, a ferromagnet 33, a nonmagnet 34, a ferromagnet 35, and a nonmagnet 36.

The ferromagnet 31 is a conductive layer (conductive film) having ferromagnetism. The ferromagnet 31 has a magnetization easy axis direction in a direction perpendicular to the film surface (Z direction). The magnetization direction of the ferromagnet 31 changes by applying a torque (torque equal to or larger than the magnetization reversal threshold of the ferromagnet 31) of a magnitude that can reverse the magnetization direction of the ferromagnet 31 to the magnetoresistive effect element MTJ.

The ferromagnet 31 may include at least one element of iron (Fe), cobalt (Co), and nickel (Ni). In addition, the ferromagnet 31 may further include boron (B). More specifically, for example, the ferromagnet 31 includes cobalt iron boron (CoFeB), iron boride (FeB), or cobalt boride (CoB). The ferromagnet 31 is used as a storage layer SL of the MTJ element.

The nonmagnet 32 is provided below a lower surface of the ferromagnet 31. The nonmagnet 32 is an insulating layer (insulating film) having nonmagnetism. The nonmagnet 32 is used as a tunnel barrier layer TB of the MTJ element.

The nonmagnet 32 is provided between the ferromagnet 31 and the ferromagnet 33, and forms a magnetic tunnel junction together with the ferromagnet 31 and the ferromagnet 33.

In a case where an initial amorphous layer such as cobalt iron boron (CoFeB) is used for the interface layer of the ferromagnet 31, the nonmagnet 32 functions as a seed material to be a main material (nucleus) for growing a crystalline film from the interface with the ferromagnet 31 in the crystallization treatment of the ferromagnet 31. Similarly, in a case where cobalt iron boron (CoFeB) is used as the interface layer of the ferromagnet 33, the nonmagnet 32 also functions as a seed material for the ferromagnet 33. Here, the initial amorphous layer is a layer that is in an amorphous state immediately after film formation and crystallizes after annealing treatment. For example, the nonmagnet 32 has a tetragonal or cubic structure in which the film surface is oriented in a (001) plane.

Examples of the insulator used for the nonmagnet 32 include magnesium oxide (MgO). Magnesium oxide (MgO) has a NaCl structure. In a case where magnesium oxide (MgO) is used for the nonmagnet 32, a (001) interface of magnesium oxide (MgO) and a (001) interface of cobalt iron boron (CoFeB) are matched with each other. For this reason, cobalt iron boron (CoFeB) is crystal-grown by annealing treatment to form a (001) oriented body-centered cubic structure.

The ferromagnet 33 is provided below a lower surface of the nonmagnet 32. The ferromagnet 33 is a conductive layer having ferromagnetism. The ferromagnet 33 is used as the reference layer RL of the MTJ element. The ferromagnet 33 has a magnetization easy axis direction in a direction perpendicular to the film surface (Z direction). The magnetization direction of the ferromagnet 33 is fixed. In the example of FIG. 5, the magnetization direction of the ferromagnet 33 is a direction from the ferromagnet 33 toward the ferromagnet 31. Note that “the magnetization direction is fixed” means that the magnetization direction of the ferromagnet 33 does not change in a case where a torque having a magnitude that can reverse the magnetization direction of the ferromagnet 31 is applied to the magnetoresistive effect element MTJ.

For example, an interface layer is used for the ferromagnet 33. As an interface layer of the ferromagnet 33, an initial amorphous layer such as cobalt iron boron (CoFeB) is used.

An auxiliary ferromagnetic layer is provided in the ferromagnet 33 so as to be in contact with a surface opposite to a surface in contact with the magnesium oxide (MgO) layer in the cobalt iron boron (CoFeB) layer as an interface layer. The auxiliary ferromagnetic layer includes, for example, at least one alloy film selected from cobalt platinum (CoPt), cobalt nickel (CoNi), and cobalt palladium (CoPd). The auxiliary ferromagnetic layer is a stack such as a stacked film including Co/Pt or a stacked film including Co/Pd. The cobalt iron boron (CoFeB) layer serving as the initial amorphous layer is used by being stacked with the stacked film including CoPt, CoPd, or Co/Pt, the stacked film including Co/Pd, or the like. In this case, the interface layer of the ferromagnet 33, for example, the CoFeB layer is formed on the side of the nonmagnet 32 including MgO oriented (001) with respect to the other layers.

The nonmagnet 34 is provided below a lower surface of the ferromagnet 33. The nonmagnet 34 is a conductive layer having nonmagnetism. The nonmagnet 34 is used as the spacer layer SP of the MTJ element. The nonmagnet 34 is made of a member including, for example, one or more selected from ruthenium (Ru), osmium (Os), rhodium (Rh), iridium (Ir), vanadium (V), and chromium (Cr). For example, the film thickness of the nonmagnet 34 is 2 nanometers (nm) or less.

The ferromagnet 35 is provided below a lower surface of the nonmagnet 34. The ferromagnet 35 is a conductive layer having ferromagnetism. The ferromagnet 35 is used as a shift cancelling layer SCL of the MTJ element. The ferromagnet 35 has a magnetization easy axis direction in a direction perpendicular to the film surface (Z direction). The magnetization direction of the ferromagnet 35 is fixed. In the example of FIG. 5, the magnetization direction of the ferromagnet 35 is a direction from the ferromagnet 33 toward the ferromagnet 35. The ferromagnet 35 includes, for example, at least one member selected from cobalt platinum (CoPt), cobalt nickel (CoNi), and cobalt palladium (CoPd). The ferromagnet 35 may be a stack such as a stacked film including Co/Pt or a stacked film including Co/Pd.

The ferromagnet 33 and the ferromagnet 35 are anti-ferromagnetically coupled by the nonmagnet 34. In other words, the ferromagnet 33 and the ferromagnet 35 are coupled so as to have magnetization directions antiparallel to each other. Such a binding structure of the ferromagnet 33, the nonmagnet 34, and the ferromagnet 35 is called a synthetic anti-ferromagnetic (SAF) structure. With the SAF structure, the ferromagnet 35 can offset the influence of the stray field of the ferromagnet 33 on the change in the magnetization direction of the ferromagnet 31. As a result, the ferromagnet 35 can reduce the substantial stray field of the ferromagnet 33.

The nonmagnet 36 is provided below a lower surface of the ferromagnet 35. The nonmagnet 36 is a conductive layer having nonmagnetism. The nonmagnet 36 is used as a base layer UL of the MTJ element. The nonmagnet 38 includes, for example, at least one member selected from zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The magnetoresistive effect element MTJ can take either a low resistance state or a high resistance state depending on whether the relative relationship (magnetization alignment state) between the magnetization directions of the storage layer SL and the reference layer RL is parallel or antiparallel. According to the present embodiment, the magnetization direction of the storage layer SL with respect to the magnetization direction of the reference layer RL is controlled by applying a write current to such a magnetoresistive effect element MTJ. Specifically, a write method using spin transfer torque (STT) generated by applying a current to the magnetoresistive effect element MTJ is adopted.

In a case where a write current Ic0 having a certain magnitude flows in the magnetoresistive effect element MTJ in the direction from the storage layer SL toward the reference layer RL, that is, in the direction of the arrow A1 in FIG. 5, the relative relationship between the magnetization directions of the storage layer SL and the reference layer RL becomes parallel. In a case where the relative relationship between the magnetization directions is the parallel state, the resistance value of the magnetoresistive effect element MTJ is the lowest, and the magnetoresistive effect element MTJ is set to the low resistance state. This low resistance state is referred to as a “parallel (P) state”. The P state of the magnetoresistive effect element MTJ is defined as, for example, a state of data “0”.

In a case where the write current Ic1 flows in the magnetoresistive effect element MTJ in the direction from the reference layer RL toward the storage layer SL, that is, in the direction of the arrow A2 in FIG. 5, the relative relationship between the magnetization directions of the storage layer SL and the reference layer RL is antiparallel. In a case where the relative relationship between the magnetization directions is the antiparallel state, the resistance value of the magnetoresistive effect element MTJ is the highest, and the magnetoresistive effect element MTJ is set to the high resistance state. This high resistance state is called an “anti-parallel (AP) state”. The AP state of the magnetoresistive effect element MTJ is defined as, for example, a state of data “1”. For example, the write current Ic1 is larger than the write current Ic0.

Note that the manner of specifying the data “1” and the data “0” is not limited to the above-described example. For example, the P state may be defined as data “1” and the AP state may be defined as data “0”.

Note that the write operation and the read operation of the magnetic memory 1 according to the present embodiment are executed using a known technique.

According to the present embodiment, the intermediate electrode 24 including the conductor 241 containing (including) a high melting point metal element is provided between the switching element SEL and the magnetoresistive effect element MTJ.

The conductor 241 in the intermediate electrode 24 can suppress deterioration of surface roughness of the upper surface of the intermediate electrode 24 even in a case where the upper surface of the member (layer) 23 constituting the switching element SEL is rough.

In addition, according to the embodiment, the conductor 242 having an amorphous structure is included between the magnetoresistive effect element MTJ and the conductor 241. This suppresses the crystal structure of the conductor 241 from affecting the structure and/or properties of the layers constituting the magnetoresistive effect element MTJ. For example, the influence of the intermediate electrode 24 on the structure and/or properties of the nonmagnet 36 functioning as the base layer UL in the magnetoresistive effect element MTJ is suppressed.

As a result, in the magnetic memory 1 according to the present embodiment, the characteristics of the magnetoresistive effect element MTJ can be improved.

### 1.2 Manufacturing Apparatus

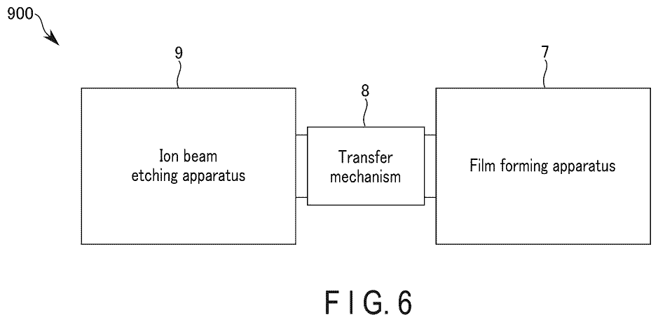

A configuration of a manufacturing apparatus used for manufacturing the magnetic memory 1 according to the first embodiment will be described with reference to FIGS. 6 to 8.

FIG. 6 is a block diagram schematically showing a manufacturing system for manufacturing the magnetic memory according to the present embodiment.

A manufacturing system 900 includes a film forming apparatus 7, a transfer mechanism 8, and an etching apparatus 9.

The film forming apparatus 7 is an apparatus for forming a plurality of members (layers, films) such as the above-described ferromagnet, nonmagnet, conductor (for example, an electrode), and insulator. For example, the film forming apparatus 7 forms various members on a wafer by various film forming techniques such as a vacuum evaporation method, a sputtering method, an atomic layer deposition (ALD) method, or a chemical vapor deposition (CVD) method.

The film forming apparatus 7 is connected to the etching apparatus 9 via the transfer mechanism 8.

The transfer mechanism 8 transfers the wafer from the film forming apparatus 7 to the etching apparatus 9 or from the etching apparatus 9 to the film forming apparatus 7 while maintaining the vacuum.

The etching apparatus 9 etches various members formed on the wafer based on a certain pattern. According to the present embodiment, the etching apparatus 9 is an ion beam etching apparatus (IBE apparatus).

Other semiconductor manufacturing apparatuses (not illustrated) such as a reactive ion etching apparatus, a chemical mechanical polishing (CMP) apparatus, and an exposure apparatus may be further connected to the transfer mechanism 8.

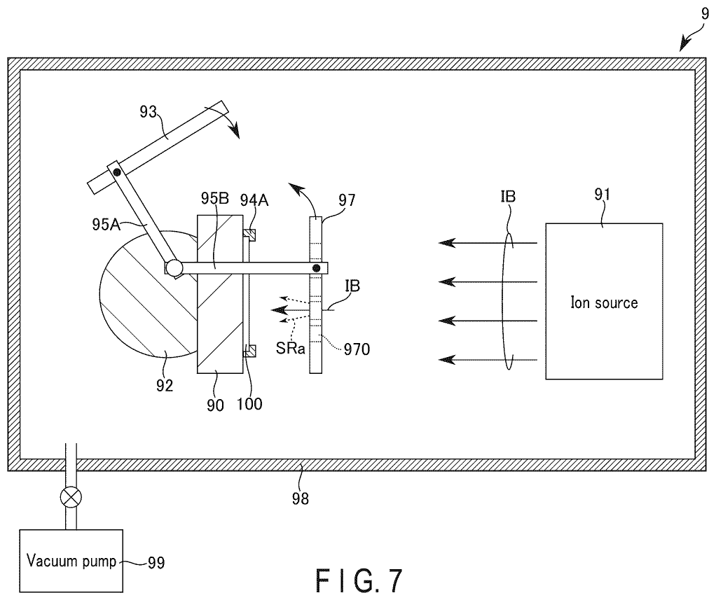

FIG. 7 is a schematic diagram showing a configuration example of the ion beam etching apparatus 9 according to the present embodiment.

As shown in FIG. 7, the ion beam etching apparatus 9 according to the present embodiment includes a wafer holding unit 90, an ion source 91, a position control mechanism 92, a shutter 93, a shutter holding unit 95A, a target holding unit 95B, a vacuum chamber 98, a vacuum pump 99, and the like.

In use of the apparatus, a wafer 100 and a target 97 are displaced in the ion beam etching apparatus 9.

The vacuum chamber 98 is a housing capable of maintaining high airtightness (vacuum state). The vacuum pump 99 is connected to the vacuum chamber 98. The vacuum pump 99 exhausts air in the vacuum chamber 98 and sets the inside of the vacuum chamber 98 to an ultra-high vacuum state.

The wafer holding unit 90, the ion source 91, the position control mechanism 92, the shutter 93, the shutter holding unit 95A, and the target holding unit 95B are provided in the vacuum chamber 98.

The wafer holding unit 90 holds the wafer 100 on which the members of the magnetic memory 1 are formed. The wafer holding unit 90 includes a wafer clamp unit 94A. The wafer 100 is fixed to the wafer holding unit 90 by the wafer clamp unit 94A. The wafer holding unit 90 is connected to the position control mechanism 92. The position of the wafer holding unit 90 is controlled by the position control mechanism 92. As a result, the position (for example, the angle) of the wafer 100 with respect to the ion source 91 can be controlled.

The ion source 91 is disposed in the vacuum chamber 98 so as to face the wafer holding unit 90. The ion source 91 outputs an ion beam IB of argon (Ar) toward the wafer holding unit 90. The wafer 100 on the wafer holding unit 90 is irradiated with the ion beam IB. The member on the wafer 100 is etched by the ion beam IB. The ion source 91 can control acceleration energy, an emission angle, and an emission range of the ion beam IB. The emission angle of the ion beam IB is an angle with respect to a direction perpendicular to an upper surface of the wafer 100. The emission angle of the ion beam IB may be controlled within a range of 0 degrees to 90 degrees. Note that the emission angle of the ion beam IB can also be controlled by controlling the angle of the wafer holding unit 90.

The position control mechanism 92 drives the wafer holding unit 90, the shutter holding unit 95A, and the target holding unit 95B based on an instruction input to an input mechanism (not illustrated) of the ion beam etching apparatus 9. As a result, the position of the wafer 100, the position of the shutter 93, and the position of the target 97 are controlled.

The shutter 93 is connected to the shutter holding unit 95A. The shutter holding unit 95A holds the shutter 93. The shutter holding unit 95A is driven under the control of the position control mechanism 92. With this structure, the position of the shutter 93 in the vacuum chamber 98 is controlled. In a case where the irradiation of the wafer 100 with the ion beam IB is blocked when the ion source 91 is driven, the shutter 93 is placed on the path of the ion beam IB between the wafer holding unit 90 and the ion source 91 by the shutter holding unit 95A and the position control mechanism 92. In a case where the wafer 100 is irradiated with the ion beam IB, the shutter 93 is placed at a position out of the path of the ion beam IB between the wafer holding unit 90 and the ion source 91 by the shutter holding unit 95A and the position control mechanism 92.

The target holding unit 95B holds the target 97. The target holding unit 95B is driven under the control of the position control mechanism 92. As a result, the position of the target 97 in the vacuum chamber 98 is controlled. The target holding unit 95B can be controlled independently of the shutter holding unit 95A by the position control mechanism 92.

The target 97 is provided in the vacuum chamber 98 to form a member of the magnetic memory 1 in the ion beam etching apparatus 9. In a case where the member of the magnetic memory 1 is formed on the wafer 100 using the target 97, the target 97 is placed on the path of the ion beam IB between the wafer holding unit 90 and the ion source 91 by the target holding unit 95B and the position control mechanism 92.

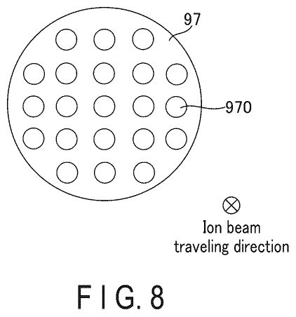

FIG. 8 is a plan view showing a structural example of the target 97 as viewed from the traveling direction of the ion beam in the manufacturing apparatus (ion beam etching apparatus) 9 according to the present embodiment.

The target 97 in FIG. 8 includes a material for forming the conductor (member including a high melting point metal element) 241 of the intermediate electrode 24. For example, the target 97 is an object (plate) made of at least one of titanium (Ti), tantalum (Ta), tungsten (W), titanium nitride (TiN), tantalum nitride (TaN), and tungsten nitride (WN).

A plurality of through holes 970 is provided in the target 97. The through holes 970 extend along the traveling direction of the ion beam.

In a state where the target 97 is placed between the wafer holding unit 90 and the ion source 91, the ion beam IB passes through the through holes 970. The target member (target atom or target molecule) SRa on the inner walls of the through holes 970 is sputtered by the collision between the ion beam IB and the target 97 in the through holes 970 during the passage of the ion beam IB. The sputtered target member SRa reaches the wafer 100. The sputtered target member SRa is deposited on a member (layer) on the wafer 100 or implanted into a member on the wafer 100.

As a result, a member (layer) formed from the target 97 is formed on the wafer 100.

For example, the position of the conductor 241 in the intermediate electrode 24 can be controlled by controlling the acceleration energy (intensity) of the ion beam IB with which the through hole 970 is irradiated. As a more specific example, in a case where the acceleration energy of the ion beam IB is high, the member SRa sputtered from the target 97 enters a deep position in another member (for example, a member made of carbon). In this case, the conductor 241 is formed at a position close to the switching element SEL (element 23) in another member. As another more specific example, in a case where the acceleration energy of the ion beam IB with which the through hole 970 is irradiated is low, the member SRa sputtered from the target 97 enters a shallow position in another member (for example, a member made of carbon) or is deposited on the surface of the another member. In this case, the conductor 241 is formed at a position close to the magnetoresistive effect element MTJ (element 25) in the another member.

In a case where the layer including the high melting point metal element is formed on the member on the wafer 100, the target 97 is placed between the wafer 100 and the ion source 91 so as to overlap the wafer 100. With this configuration, the sputtered target member SRa is relatively uniformly deposited on the member on the wafer 100 or implanted into the member.

For example, by controlling the emission angle of the ion beam IB, it is possible to control the ion beam IB so as not to reach the wafer 100 through the through hole 970 in a state where the target 97 is placed between the wafer 100 and the ion source 91.

The ion beam etching apparatus 9 according to the present embodiment can execute etching of the members of the magnetic memory 1 by the ion beam IB and formation of the members of the magnetic memory 1 on the wafer 100 in one apparatus.

With this configuration, the ion beam etching apparatus 9 according to the present embodiment can reduce the number of transfers of the wafer 100 between the film forming apparatus 7 and the ion beam etching apparatus 9.

As a result, the ion beam etching apparatus 9 of the present embodiment can improve the manufacturing efficiency of the memory device (for example, a magnetic memory).

### 1.3 Manufacturing Method

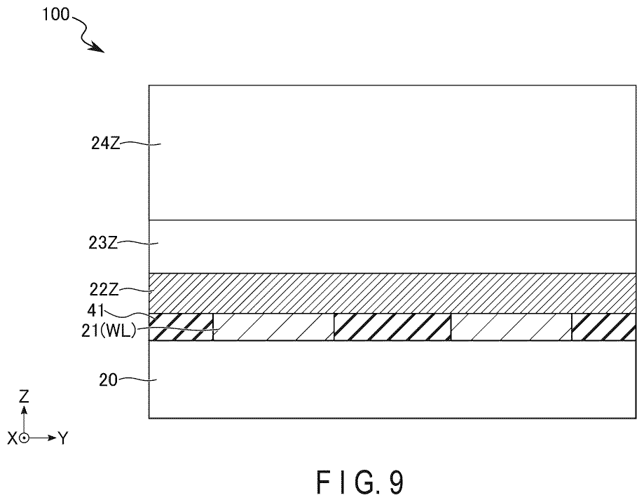

The manufacturing method of the magnetic memory 1 according to the present embodiment using the ion beam etching apparatus 9 according to the present embodiment will be described with reference to FIGS. 9 to 14.

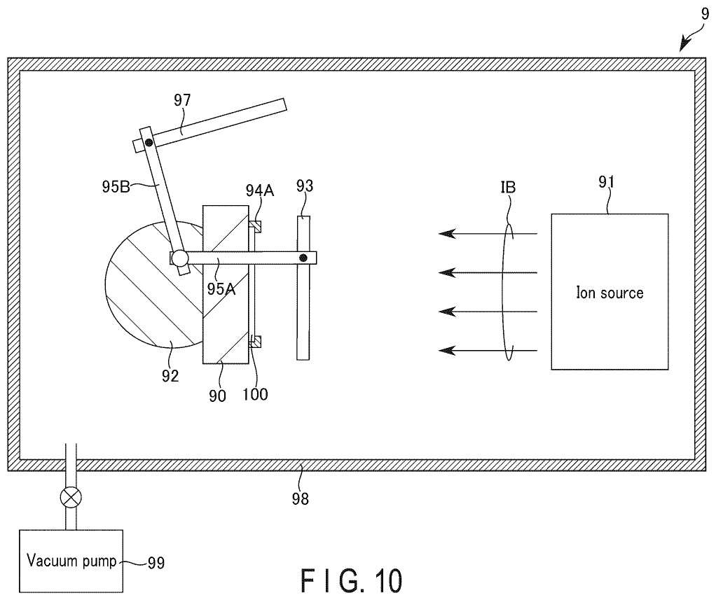

FIGS. 9, 12, and 14 are cross-sectional process diagrams showing respective processes of the magnetic memory manufacturing method according to the present embodiment. FIGS. 10, 11, and 13 are schematic diagrams showing a state of the ion beam etching apparatus 9 in each step of the manufacturing method of the magnetic memory 1 according to the present embodiment.

As shown in FIG. 9, a plurality of conductors 21 to be interconnects (for example, the word lines WL) are formed on the substrate 20 of the wafer 100 by various semiconductor manufacturing apparatuses. The insulator 41 is embedded in a space between the conductors 21 by various semiconductor manufacturing apparatuses.

The conductive layer (electrode layer) 22Z to be the lower electrode BE is formed on the conductor 21 and the insulator 41 by the film forming apparatus 7.

A member (variable resistance layer) 23Z for forming the switching element SEL is formed on the conductive layer 22Z by the film forming apparatus 7.

A conductive layer (member) 24Z for forming the intermediate electrode ME is formed on the variable resistance layer 23Z by the film forming apparatus 7. The conductive layer 24Z is made of, for example, at least one member selected from carbon (C) and carbon nitride (CN).

After the formation of the conductive layer 24Z, the wafer 100 is transferred from the film forming apparatus 7 to the ion beam etching apparatus 9 via the transfer mechanism 8 for etch-back of an upper surface of the conductive layer 24Z.

As shown in FIG. 10, in the ion beam etching apparatus 9, the wafer 100 on which the members of the magnetic memory 1 are formed is mounted on the wafer holding unit 90.

During a period from the activation of the ion source 91 to the driving under a desired condition, the shutter 93 is placed between the wafer holding unit 90 and the ion source 91 by the shutter holding unit 95A and the position control mechanism 92. The shutter 93 prevents the wafer 100 from being irradiated with the ion beam IB in an unstable energy state. This prevents the member on the wafer 100 from being etched in an unintended state.

For example, in an etch-back process for planarizing the surface (upper portion) of the intermediate electrode 24, the target 97 is not placed between the wafer holding unit 90 and the ion source 91.

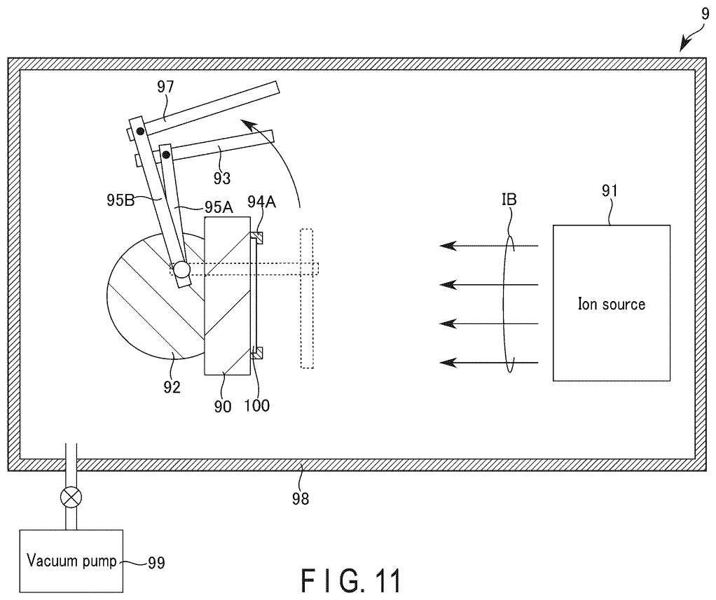

As shown in FIG. 11, after the output (acceleration energy) of the ion beam IB of the ion source 91 reaches a predetermined condition, the shutter 93 is moved from the position between the wafer holding unit 90 and the ion source 91 to another position by the shutter holding unit 95A and the position control mechanism 92. As a result, the wafer 100 is irradiated with the ion beam IB output from the ion source 91.

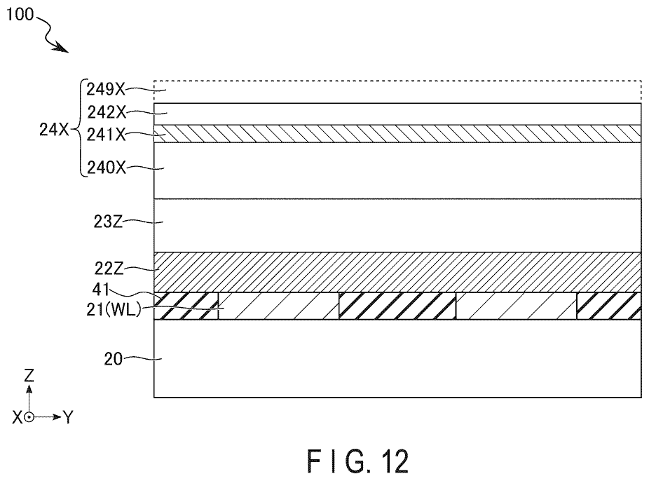

As shown in FIG. 12, an upper portion 249X of the conductive layer 24X is removed by etching back the conductor by the ion beam IB. As a result, the surface roughness of an upper surface of the conductive layer 24X is controlled. In addition, the dimension of the conductive layer 24X (intermediate electrode ME) in the Z direction is controlled by the etch-back.

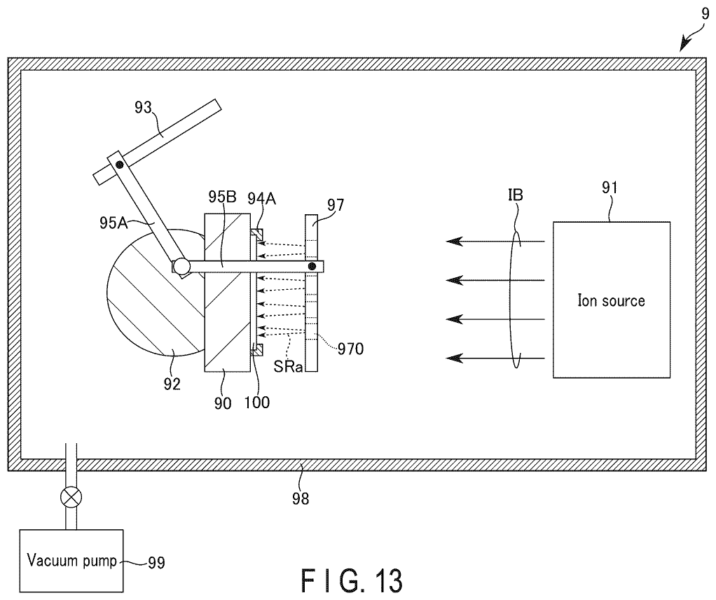

As shown in FIG. 13, after the etching back of the conductive layer 24X, the target 97 is placed between the wafer holding unit 90 and the ion source 91 by the target holding unit 95B and the position control mechanism 92 in order to form a layer made of a member including (containing) a high melting point metal element.

The ion beam IB is output toward the target 97. The emission angle of the ion beam IB is controlled such that the ion beam IB collides with the inner walls in the through holes 970. The ion beam IB can pass through the through holes 970 and be irradiated (collided) with the member on the wafer 100.

In a case where the through holes 970 are irradiated with the ion beam IB, portions of the inner walls of the through holes 970 in the target 97 is sputtered by the ion beam IB colliding with the inner wall. As a result, the sputtered target member SRa is released from the target 97. The target member SRa sputtered from the target 97 flies toward the wafer 100. The sputtered target member SRa is implanted into the conductive layer 24X according to the acceleration energy of the ion beam IB.

As a result, as shown in FIG. 12, a layer 241X including a high melting point metal element is formed between the layer 240X and the layer 242X in a conductive layer 24X.

Depending on the magnitude of the acceleration energy of the ion beam IB, the layer 241X including a high melting point metal element may be deposited on the upper surface of the member for forming the intermediate electrode. In this case, the layer 242X is formed on the layer 241X by the film forming apparatus 7.

After the formation of the layer 241X including the high melting point metal element, etch-back may be performed on the conductive layer 24Z (24X).

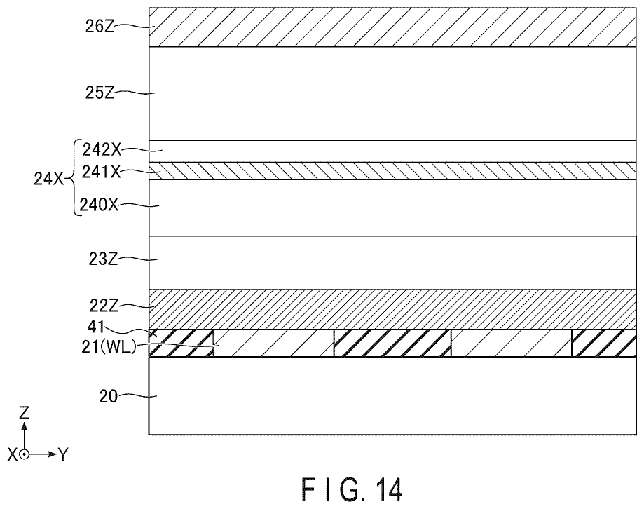

As shown in FIG. 14, after the wafer 100 including the etched back conductive layer 24X is transferred from the ion beam etching apparatus 9 to the film forming apparatus 7 via the transfer mechanism 8, the member 25Z for forming the magnetoresistive effect element MTJ is formed on the conductive layer 24X by the film forming apparatus 7.

A conductive layer (electrode layer) 26Z to be an upper electrode is formed on the member 25Z by the film forming apparatus 7. The conductive layer 26Z can also be used as, for example, a hard mask. For example, a mask (not illustrated) is formed on the conductive layer 26Z by various manufacturing apparatuses.

The wafer 100 on which the member 25Z and the conductive layer 26Z are formed is transferred from the film forming apparatus 7 to the ion beam etching apparatus 9 via the transfer mechanism 8 for etching by the ion beam IB. The wafer 100 is mounted on the wafer holding unit 90 in the ion beam etching apparatus 9.

As shown in FIG. 10, the shutter 93 is placed between the wafer holding unit 90 and the ion source 91 by the shutter holding unit 95A and the position control mechanism 92 in a period until the energy state of the ion beam IB is stabilized.

As shown in FIG. 11, after the ion beam IB is stabilized, the shutter 93 is moved from the position between the wafer holding unit 90 and the ion source 91 to another position by the shutter holding unit 95A and the position control mechanism 92. As a result, the wafer 100 is irradiated with the ion beam IB.

In a case of etching the wafer 100 on which the member 25Z and the conductive layer 26Z are formed, the target 97 is placed at a position not existing between the wafer holding unit 90 and the ion source 91 by the target holding unit 95B and the position control mechanism 92.

By the irradiation of the ion beam IB, the member on the wafer 100 is etched based on the pattern of the mask.

As a result, as shown in FIG. 4, the upper electrode TE having a predetermined shape, the magnetoresistive effect element MTJ having a predetermined shape, the intermediate electrode ME having a predetermined shape, the switching element SEL having a predetermined shape, and the lower electrode BE having a predetermined shape are formed. In this manner, the memory cell MC including the magnetoresistive effect element MTJ and the switching element SEL is formed on the conductor 21.

An insulator (not illustrated) is formed in the space between the memory cells MC by the film forming apparatus 7.

The conductor 27 serving as an interconnect (for example, the bit lines BL) is formed on the memory cell MC and the insulator by various semiconductor manufacturing apparatuses.

Through the above steps, the memory cell array 10 of the magnetic memory 1 according to the present embodiment is completed.

### 1.4 Summary

The memory device (for example, the magnetic memory) 1 according to the present embodiment includes the intermediate electrode 24 between the switching element SEL and the memory element (magnetoresistive effect element) MTJ. The intermediate electrode 24 includes the conductor 241 including (containing) a high melting point metal element between the two conductors 240 and 242.

In a case where the surface roughness of the surface of the intermediate electrode in contact with the memory element is deteriorated, the structure and/or properties of the members constituting the memory element are deteriorated. For this reason, the characteristics of the memory element may be deteriorated. In addition, due to the deterioration of the surface roughness of the intermediate electrode, the member constituting the intermediate electrode is likely to be mixed into the memory element.

In the memory device 1 according to the present embodiment, deterioration of the surface roughness of the surface of the intermediate electrode 24 in contact with the memory element MTJ can be suppressed by the conductor 241 including a high melting point metal element. As a result, in the memory device 1 according to the present embodiment, it is possible to suppress deterioration of the properties of the constituent members of the memory element MTJ. In addition, in the memory device 1 according to the present embodiment, it is possible to suppress mixing of the constituent members of the intermediate electrode 24 into the memory element MTJ.

As a result, the memory device 1 according to the present embodiment can suppress deterioration of characteristics of the memory element.

The ion beam etching apparatus 9 according to the present embodiment includes the target holding unit 95B that holds the target 97 including a high melting point metal element. The target 97 includes the through holes 970 through which the ion beam IB can pass through.

In a case where the ion beam IB enters the through holes 970, portions of the inner walls of the through holes 970 are sputtered by the ion beam IB. With this configuration, in the ion beam etching apparatus 9 according to the present embodiment, the sputtered target member SRa flies toward the wafer 100.

As a result, the ion beam etching apparatus 9 according to the present embodiment can execute etching of the constituent members of the memory device 1 by the ion beam and formation of the constituent members of the memory device 1 such as the conductor (member) 241 including the high melting point metal element of the intermediate electrode 24 in the memory cell MC in one apparatus.

As a result, the ion beam etching apparatus 9 according to the present embodiment can efficiently manufacture the memory device.

### 2. Second Embodiment

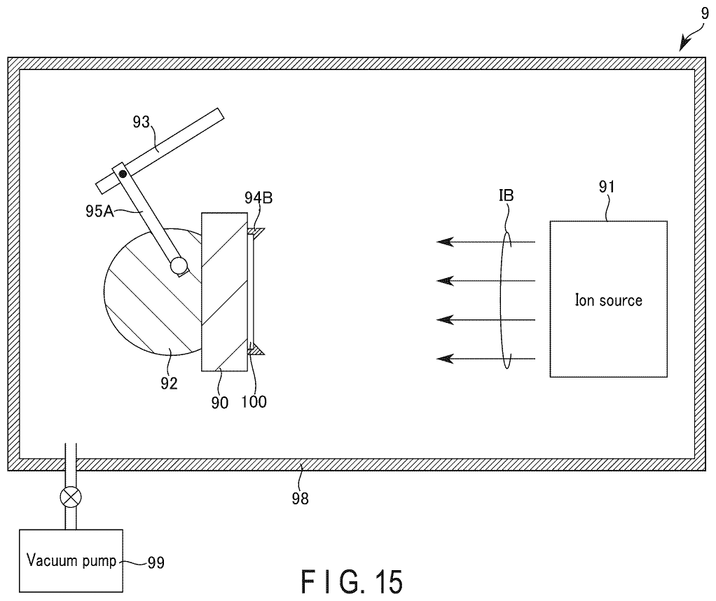

A manufacturing apparatus according to a second embodiment will be described with reference to FIGS. 15 to 17.

FIG. 15 is a schematic diagram showing a configuration example of a manufacturing apparatus (an ion beam etching apparatus) 9 used for manufacturing a magnetic memory 1 according to the present embodiment.

As shown in FIG. 15, in the ion beam etching apparatus 9 according to the present embodiment, a wafer clamp unit 94B is formed of a material including a high melting point metal element. The wafer clamp unit 94B includes one or more selected from titanium (Ti), tantalum (Ta), tungsten (W), titanium nitride (TiN), tantalum nitride (TaN), and tungsten nitride (WN).

The wafer clamp unit 94B is used as a supply source (target) for forming a conductor (layer) 241 including a high melting point metal element of an intermediate electrode 24.

The side surface of the wafer clamp unit 94B is preferably inclined at a certain angle φ with respect to an upper surface of a wafer 100. The angle φ is larger than 0 degrees and smaller than 90 degrees.

The wafer clamp unit 94B serving as a target can be disposed in the vicinity of the wafer 100. Therefore, even in a case where the acceleration energy of the ion beam IB is relatively low, the sputtered member SRb can be implanted into the member on the wafer 100. For example, in a case where the acceleration energy of the ion beam IB is about 100 eV, the sputtered member SRb is implanted into the inside of the member (for example, a carbon layer) on the wafer 100.

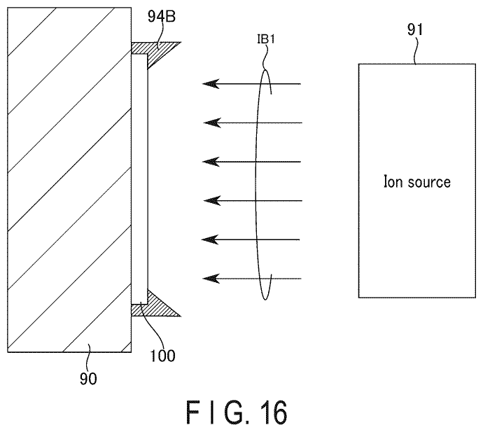

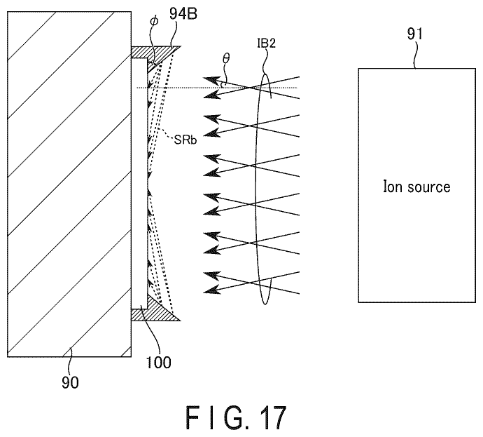

FIGS. 16 and 17 are schematic diagrams showing a state of the ion beam etching apparatus 9 according to the present embodiment in the manufacturing process of the magnetic memory 1 according to the present embodiment.

As shown in FIG. 16, during normal etching by irradiation with the ion beam, the emission angle and/or the emission range of an ion beam IB1 in the ion source 91 is controlled such that the wafer clamp unit 94B is not irradiated with the ion beam IB1.

With this configuration, only the wafer 100 is irradiated with the ion beam IB1 and the wafer clamp unit 94B is not irradiated.

Therefore, during normal etching by the ion beam IB, the member of the wafer clamp unit 94B is not mixed into the member on the wafer 100.

As shown in FIG. 17, at the time of forming the layer 241 including the high melting point metal element by irradiation with the ion beam, the emission angle and/or the emission range of an ion beam IB2 in the ion source 91 is controlled such that the wafer clamp unit 94B is irradiated with the ion beam IB2. For example, the emission angle θ of the ion beam IB2 in the case of forming the layer 241 is made larger than the emission angle of the ion beam IB1 in the case of normal etching so that the ion beam IB2 collides with the wafer clamp unit 94B. Alternatively, the emission range of the ion beam IB2 in the case of forming the layer 241 is made larger than the emission range of the ion beam IB1 in the case of normal etching.

A member SRb of the wafer clamp unit 94B sputtered by the ion beam IB2 is implanted into the conductive layer (member) 24Z on the wafer 100 at a position corresponding to the magnitude of the acceleration energy of the ion beam IB2. Note that the member SRb of the wafer clamp unit 94B may be deposited on a conductive layer 24Z depending on the magnitude of the acceleration energy of the ion beam IB2.

As a result, in the ion beam etching apparatus 9, the layer 241 made of the material (member SRb) of the wafer clamp unit 94B is formed on the wafer 100. The layer 241 includes a high melting point metal element.

For example, the upper portion of the member (for example, the conductive layer 24Z) on the wafer 100 can be etched back by the ion beam IB2 with which the wafer 100 is irradiated.

In a case where the wafer clamp unit 94B is used as a supply source for forming a member including a high melting point metal element as in the present embodiment, the configuration of the ion beam etching apparatus 9 can be simplified.

The ion beam etching apparatus 9 according to the present embodiment can obtain the same effects as those of the above-described embodiment.

### 3. Modification

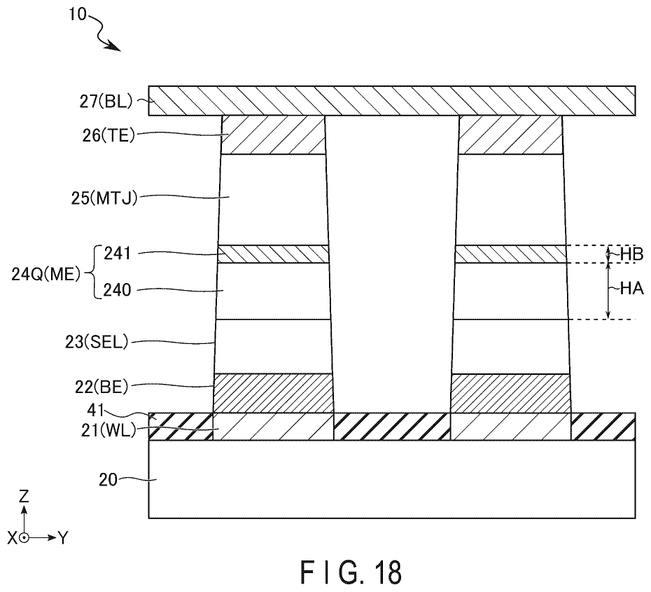

Modifications of a memory device and a manufacturing apparatus according to one or more of the embodiments will be described with reference to FIGS. 18 to 20.

FIG. 18 is a cross-sectional view showing a modification of a magnetic memory 1 according to one or more of the embodiments.

As shown in FIG. 18, an intermediate electrode 24Q includes two conductors 240 and 241. The intermediate electrode 240 does not include any other conductor between a magnetoresistive effect element MTJ and the conductor 241.

The conductor 241 including a high melting point metal element is in direct contact with the magnetoresistive effect element MTJ.

As described above, according to the present modification, the intermediate electrode 240 is a stack having a two-layer structure including the two conductors 240 and 241.

Even in a case where the intermediate electrode 24Q has the structure illustrated in FIG. 18, the magnetic memory 1 according to the modification can obtain the effects of one or more of the above-described embodiments.

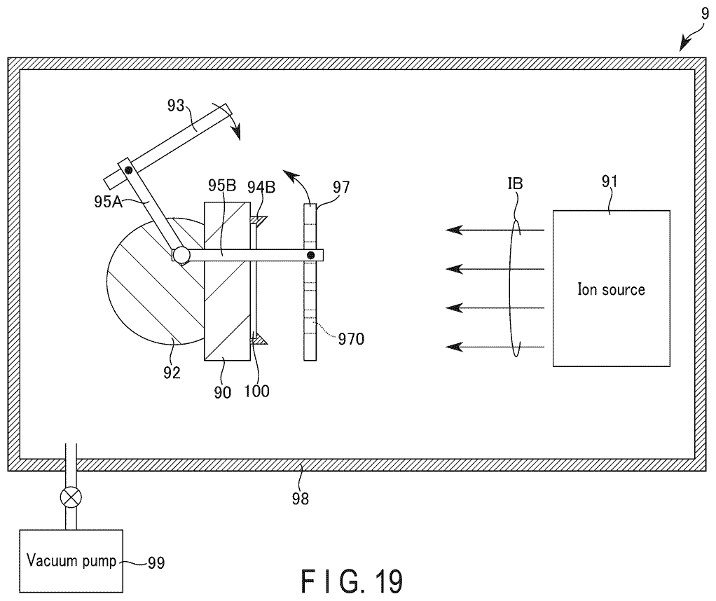

FIG. 19 is a cross-sectional view showing a modification of an ion beam etching apparatus 9 according to one or more of the embodiments.

As shown in FIG. 19, the ion beam etching apparatus 9 may include a target holding unit 95B that holds a target 97 having through holes 970, and a wafer clamp unit 94B made of the same material as the target 97.

By irradiating the target 97 and the wafer clamp unit 94B with the ion beam, a member including a high melting point metal element from the target 97 and a member including a high melting point metal element from the wafer clamp unit 94B are implanted into a conductive layer 24Z made of carbon (or carbon nitride) or deposited on the conductive layer 24Z.

Even in a case where the ion beam etching apparatus 9 has the configuration illustrated in FIG. 19, the ion beam etching apparatus 9 according to the modification can obtain the effects of one or more of the above-described embodiments.

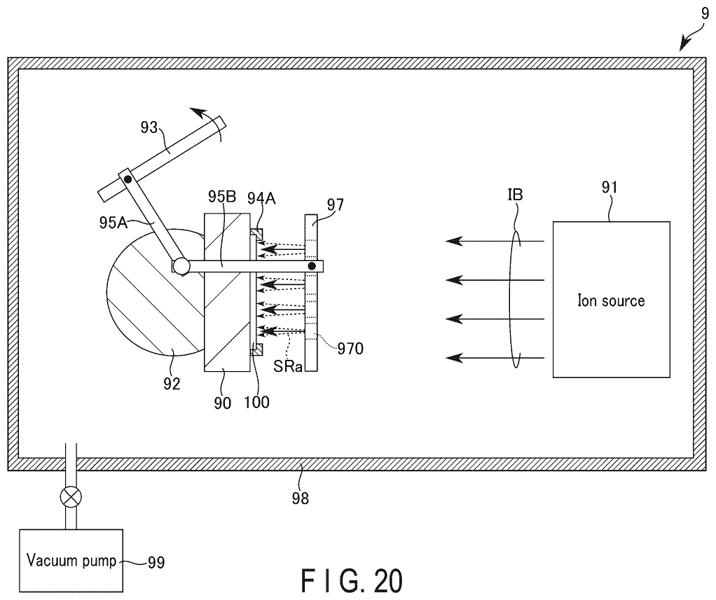

FIG. 20 is a diagram showing a modification of a manufacturing method of a magnetic memory 1 according to one or more of the embodiments.

As shown in FIG. 20, etch back of a member on a wafer 100 and formation of a layer including a high melting point metal element may be performed substantially simultaneously.

In this case, a target 97 having through holes 970 is placed between a wafer holding unit 90 and an ion source 91 in a case of etching back a conductive layer 24Z.

A certain ion beam IB passes through the through holes 970 of the target 97 and reaches the wafer 100. With this configuration, as shown in FIG. 12, the upper portion 249X of the conductive layer 24X on the wafer 100 is etched back.

In addition, another ion beam IB collides with the target 97 in the through hole 970. With this configuration, a sputtered target member SRa flies toward the wafer 100. As a result, a layer (conductor) 241X including a high melting point metal element is formed in the etched back conductive layer 24X or on the conductive layer 24X.

The modification of the manufacturing method of the magnetic memory 1 according to one or more of the embodiments can improve the efficiency of the manufacturing process of the magnetic memory 1.

### 4. Others

In one or more of the above-described embodiments, a memory device (magnetic memory) 1 in which a magnetoresistive effect element is used as a memory element MTJ is illustrated. However, the type of the memory element MTJ is not limited as long as an intermediate electrode 24 between the memory element MTJ and a switching element SEL has a structure including a layer 241 including a high melting point metal element.

For example, the memory device 1 according to one or more of the embodiments may be a memory device (for example, a resistive change memory such as a resistive random access memory (ReRAM)) using a transition metal oxide element having a variable resistance characteristic as a memory element, a memory device (for example, a phase change memory such as a phase change random access memory (PCRAM)) using a phase change element as a memory element, or a memory device (for example, a ferroelectric memory such as a ferroelectric random access memory (FeRAM)) using a ferroelectric element as a memory element.

A manufacturing apparatus (ion beam etching apparatus) 9 according to one or more of the above-described embodiments may be used for other than manufacturing of a memory device. For example, the manufacturing apparatus 9 according to one or more of the embodiments may be used for manufacturing a semiconductor device such as a processor, an image sensor, or a power device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing apparatus comprising:
a wafer holding unit configured to hold a wafer;
an ion source configured to output an ion beam;
a shutter holding unit configured to hold a shutter and place the shutter between the wafer holding unit and the ion source in a case of preventing irradiation of the wafer with the ion beam; and
a target holding unit configured to hold a target including a through hole, and place the target between the wafer holding unit and the ion source in a case of forming, on the wafer, a first layer including a member of the target.

2. The manufacturing apparatus according to claim 1, further comprising:
a control mechanism connected to the shutter holding unit and the target holding unit and configured to move the shutter holding unit and the target holding unit to control a position of the shutter and a position of the target.

3. The manufacturing apparatus according to claim 1, wherein
the target includes a high melting point metal element.

4. The manufacturing apparatus according to claim 1, wherein
the target includes at least one of titanium (Ti), tantalum (Ta), tungsten (W), titanium nitride (TiN), tantalum nitride (TaN), and tungsten nitride (WN).

5. The manufacturing apparatus according to claim 1, wherein
the member of the wafer is etched by the ion beam.

6. The manufacturing apparatus according to claim 1, wherein
the first layer is formed on the wafer by sputtering the target with the ion beam that irradiates the through hole.

7. The manufacturing apparatus according to claim 6, wherein
a second layer on the wafer is etched by the ion beam that has passed through the through hole.

8. The manufacturing apparatus according to claim 7, wherein
the first layer includes at least one of titanium (Ti), tantalum (Ta), tungsten (W), titanium nitride (TiN), tantalum nitride (TaN), and tungsten nitride (WN), and
the second layer includes at least one of carbon (C) and carbon nitride (CN).

9. The manufacturing apparatus according to claim 1, wherein
the wafer including a first member of a first element and a second member formed on the first member is disposed on the wafer holding unit,
the second member is etched by a first ion beam,
the target is placed between the wafer and the ion source,
the target is irradiated with a second ion beam, and a first layer including a member of the target is formed in the second member or on the second member,
the wafer on which a third member of a second element is formed above the second member after formation of the first layer is disposed on the wafer holding unit, and
the first member, the second member, the first layer, and the third member are etched by a third ion beam to form a memory cell including the first element and the second element.

10. The manufacturing apparatus according to claim 9, wherein
the second member includes one of carbon and carbon nitride, and
the first layer includes a high melting point metal element.

11. The manufacturing apparatus according to claim 10, wherein
the first layer includes at least one of titanium (Ti), tantalum (Ta), tungsten (W), titanium nitride (TiN), tantalum nitride (TaN), and tungsten nitride (WN).

12. A manufacturing apparatus comprising:
a wafer holding unit configured to hold a wafer;
a wafer clamp unit configured to fix the wafer on the wafer holding unit and including a high melting point metal element; and
an ion source configured to output an ion beam, wherein
in a case of etching a member on the wafer, the wafer is irradiated with the ion beam, and in a case of forming a first layer including the high melting point metal element on the wafer, the wafer clamp unit is irradiated with the ion beam.

13. The manufacturing apparatus according to claim 12, further comprising:
a shutter holding unit configured to hold a shutter and place the shutter between the wafer holding unit and the ion source in a case of preventing irradiation of the wafer with the ion beam; and
a control mechanism connected to the shutter holding unit and configured to move the shutter holding unit to control a position of the shutter.

14. The manufacturing apparatus according to claim 12, wherein
the wafer clamp unit includes at least one of titanium (Ti), tantalum (Ta), tungsten (W), titanium nitride (TiN), tantalum nitride (TaN), and tungsten nitride (WN).

15. The manufacturing apparatus according to claim 12, wherein
the wafer including a first member of a first element and a second member formed on the first member is disposed on the wafer holding unit,
the wafer clamp unit is irradiated with the ion beam, and the first layer is formed in the second member or on the second member with a sputtered member of the wafer clamp unit,
the wafer on which a third member of a second element is formed on the second member after formation of the first layer is disposed on the wafer holding unit, and
the first member, the second member, the first layer, and the third member are etched by the ion beam to form a memory cell including the first element and the second element.

16. The manufacturing apparatus according to claim 15, wherein
the second member includes one of carbon and carbon nitride, and
the first layer includes at least one of titanium (Ti), tantalum (Ta), tungsten (W), titanium nitride (TiN), tantalum nitride (TaN), and tungsten nitride (WN).

17. A memory device comprising:
a memory element;
a switching element; and
an electrode between the memory element and the switching element, wherein
the electrode includes:
a first conductor including one of carbon (C) and carbon nitride (CN); and
a second conductor including a high melting point metal element, and
the second conductor is in direct contact with the memory element.

18. The memory device according to claim 17, wherein
the second conductor includes at least one of titanium (Ti), tantalum (Ta), tungsten (W), titanium nitride (TiN), tantalum nitride (TaN), and tungsten nitride (WN).

19. The memory device according to claim 17, wherein
the memory element is a magnetoresistive effect element.
